(19) United States
(12) Patent Application Publication
(10) Pub. No.: US 2004/0110381 A1
(43) Pub. Date: Jun. 10, 2004

(54) Chemical mechanical polishing method and apparatus

(75) Inventor: Hideaki Yoshida, Osaka (JP)

Correspondence Address: Jack Q. Lever, Jr., McDERMOTT, WILL & EMERY, 600 Thirteenth Street, N.W., Washington, DC, 20005-3096, US

(73) Assignee: MATSUSHITA ELECTRIC INDUSTRIAL CO., LTD.

(21) Appl. No.: 10/718,607

(22) Filed: Nov. 24, 2003

(30) Foreign Application Priority Data
Dec. 4, 2002 (JP) 2002-352722

(51) Int. Cl. H01L 21/302; H01L 21/461; B24B 5/00; B24B 29/00

(52) U.S. Cl. 438/692; 438/691; 451/288; 451/285

(57) ABSTRACT

In a CMP process for polishing copper and a barrier metal formed on a substrate to form a buried copper interconnect, a polishing pad is subjected to dressing under a dressing pressure of 29 g/cm² so that the surface roughness of the polishing pad becomes 3 μm to 5 μm inclusive. Thereby, dishing of the copper interconnect can be reduced as compared with a known method without reducing the removal rate of the copper and barrier metal.

### CROSS-REFERENCE TO RELATED APPLICATIONS

This application claims the benefit of Japanese Patent Application No. 2002-352722 filed on Dec. 4, 2002, which is herein incorporated by reference.

### BACKGROUND OF THE INVENTION

The present invention relates to a chemical mechanical polishing method and a chemical mechanical polishing apparatus that are used for a multilevel interconnection process and a device isolation process for a semiconductor integrated circuit.

Chemical Mechanical Polishing (CMP) is a technique for planarizing a substrate surface, and this is essential for forming a buried copper interconnect and an STI (Shallow Trench Isolation).

FIGS. 8A through 8D and 9A through 9C are cross sectional views showing a typical method for forming a buried copper interconnect using the CMP. The typical method for forming a buried copper interconnect will be described hereinafter with reference to the drawings.

First, as shown in FIG. 8A, an integrated circuit is formed on a semiconductor substrate, and an inter-level dielectric 1 is formed on the substrate. To simplify the description, only the inter-level dielectric 1 is shown.

Next, as shown in FIG. 8B, an interconnect trench 2 is formed in the top surface of the inter-level dielectric 1 by using a known lithography technique and a known etching technique.

Next, as shown in FIGS. 8C and 8D, a barrier metal 3 is formed on the top surface of the inter-level dielectric 1 including the interconnect trench 2 by sputtering, and subsequently a seed layer 4 made of copper (Cu) is formed on the barrier metal 3. Here, the barrier metal 3 is composed of chemically stable tantalum nitride (TaN) or tantalum (Ta), or a film obtained by laminating them.

Next, as shown in FIG. 9A, a copper film is formed by electrolytic plating such that the interconnect trench 2 is sufficiently filled in. In later process steps, a combination of this copper film and the seed layer 4 is referred to as a copper film 5.

Next, as shown in FIG. 9B, an annealing process of the copper film 5 is performed, the substrate is then moved into the chemical mechanical polishing apparatus, and CMP is performed to remove redundant copper. Thereby, a copper interconnect 5a is formed. At this time, the copper film 5 is polished until the barrier metal 3 is exposed.

Subsequently, as shown in FIG. 9C, the barrier metal 3 is polished until the inter-level dielectric 1 is exposed. At this time, overpolishing is often performed to prevent interconnect failure from occurring due to residual copper on the inter-level dielectric 1.

A buried copper interconnect is formed through the above-described process steps.

In this way, according to a typical method for forming a buried copper interconnect, a two-step polishing process is usually carried out as shown in FIGS. 9B and 9C. The reason is as follows: since it is more difficult for tantalum nitride or tantalum that is a material of the barrier metal to be removed by polishing than for copper, polishing need be carried out under different conditions.

More specifically, in order to selectively remove copper, the first-step polishing shown in FIG. 9B is carried out by employing slurry for oxidizing and dissolving copper, such that the removal rate of copper becomes 100 times or more as fast as that of the barrier metal 3 or the inter-level dielectric 1. The second-step polishing shown in FIG. 9C is carried out by employing slurry different from that in the first-step polishing, such that the removal rate of the barrier metal becomes equivalent to or faster than that of copper.

Next, a known chemical mechanical polishing method and a polishing apparatus used therefor will be described.

FIG. 10 is a view schematically showing the structure of a known chemical mechanical polishing apparatus. As shown in this figure, the known chemical mechanical polishing apparatus comprises a polishing table 106 to the top surface of which a polishing pad 107 is attached, a substrate carrier 109 for holding a substrate 108 to be polished, and a dresser 111 to make the surface of the polishing pad 107 rough.

When the substrate 108 is polished, the substrate 108 is put down onto the polishing pad 107 by imposing a load on the substrate carrier 109 that holds the substrate 108 with the surface of the substrate 108 to be polished being directed to the polishing pad 107. While slurry 110 is supplied on the polishing pad 107, both of the polishing table 106 and the substrate carrier 109 are rotated.

Dressing is performed on the polishing pad 107 before polishing or simultaneously with polishing. The dressing represents a process step of making the surface of the polishing pad 107 rough by rotating the disk-like dresser 111 obtained by fixing diamond particles of a few tens through one hundred and a few tens of μm thereto. Usually, the polishing pad 107 has a double-layer structure: a hard polyurethane foam is employed for the upper layer of the polishing pad 107 that will be brought into contact with the substrate 108 to be polished, while a soft nonwoven cloth is employed for the lower layer of the polishing pad 107 bonded to the polishing table 106. According to the known CMP, the dressing is performed under a pressure of approximately 70 g/cm², thereby increasing the top surface roughness of the hard polyurethane foam layer that is the upper layer of the polishing pad 107.

The dressing can prevent the substrate 108 to be polished from being brought into close contact with the polishing pad 107. Therefore, the substrate 108 can easily be taken out of the chemical mechanical polishing apparatus, thereby improving transfer reliability. In addition, abrasive grains included in the slurry 110 are favorably held in the polishing pad 107. Therefore, this method provides a high removal rate, reduction in non-uniformity of polishing within the substrate surface, reduction in non-uniformity of polishing between substrates, and the like.

### SUMMARY OF THE INVENTION

The use of the known CMP enables a homogeneous substrate surface to be favorably planarized. However, when a buried copper interconnect is formed, there exists a problem that the top surface of the copper interconnect is dented to become lower than the top surface of an inter-level dielectric located around it. This surface step height produced by CMP is called dishing. As dishing becomes larger, the interconnect resistance is increased and variation in the interconnect resistance within the same interconnect layer is increased. Furthermore, the redundant substance to be polished is partly left on an upper layer of the multi-level interconnect structure, thereby causing interconnection failure.

Conventionally, it is the selectivity of slurry, elastic deformation of a polishing pad, overpolishing in polishing for removing copper, or the like that has been considered as principal factors contributing to dishing. A description will be given hereinafter of influences exerted on the occurrence of dishing by the selectivity of slurry, the elastic deformation of the polishing pad and overpolishing in polishing for removing copper.

The selectivity of slurry will initially be described. Slurry for removing copper is prepared as described above such that the removal rate of copper becomes 100 times or more as fast as that of a barrier metal or an inter-level dielectric. As a result, after copper is removed on the inter-level dielectric by polishing, a copper interconnect is more severely dented than the barrier metal located around it due to selective polishing of copper, resulting in the occurrence of a difference in surface level due to reduction of copper, i.e., dishing. On the other hand, slurry to be used for removing the barrier metal by polishing is prepared such that the removal rate of the barrier metal becomes equivalent to or faster than that of copper or the inter-level dielectric. Therefore, the dishing is reduced to some extent by polishing the barrier metal. However, the dishing cannot be eliminated.

Next, an influence of the elastic deformation of the polishing pad will be described. The polishing pad that will be brought into contact with the substrate is made of polyurethane foam and elastically deformed in accordance with the applied pressure. Therefore, dishing occurring in the interconnect leads to the elastic deformation of the polishing pad along the dented interconnect pattern, whereby the dishing becomes larger. The wider the trace width, the more easily the polishing pad follows the interconnect pattern. Therefore, the wider the trace width, the larger dishing becomes.

Next, an influence of overpolishing in polishing for removing copper will be described. Overpolishing is performed to remove all copper partly remaining on the substrate surface after completion of copper polishing. Overpolishing is necessary for preventing a short circuit between interconnect traces from being caused by the remaining copper. However, excessive overpolishing leads to a reduction in the copper interconnect height, i.e., an expansion of the dishing.

As described so far, dishing is produced due to various factors after polishing in the known method. Thus, it has been difficult for a fine integrated circuit having a copper interconnect to ensure sufficient reliability.

Furthermore, this kind of dishing is produced not only at formation of a copper interconnect but also in a CMP process step at formation of an STI.

It is an object of the present invention to provide a chemical mechanical polishing method that can reduce dishing and a chemical mechanical polishing apparatus used for the method.

A first chemical mechanical polishing method of the present invention using a chemical mechanical polishing apparatus comprising a polishing table including a rotation mechanism, a polishing pad attached on the polishing table, a substrate carrier for holding a member to be polished, said substrate carrier including a rotation mechanism and a pressurization mechanism, and a dresser including a rotation mechanism and a pressurization mechanism, comprises the steps of: (a) dressing the polishing pad with the dresser coming in contact with the polishing pad; and (b) polishing a film using the polishing pad having a surface roughness of 6 μm to 8 μm inclusive in a pattern formation substrate including a substrate region in the top of which a trench is formed and the film with which the trench is filled in.

According to this method, the step (b) allows polishing to be performed using the polishing pad having an adequate surface roughness. Therefore, dishing produced in the film can be made smaller without reducing the removal rate and transfer reliability as compared with the known method. Thus, this method is preferably applied at formation of a buried copper interconnect, at formation of a trench isolation dielectric or the like. In the step (a), a dressing pressure of 18 g/cm² to 40 g/cm² inclusive may be applied to the dresser. Therefore, the surface roughness of the polishing pad can become adequate.

In the step (a), a dressing pressure of 24 g/cm² to 34 g/cm² inclusive may be applied to the dresser. Therefore, dishing of the film can be further reduced, and also a dresser's life can be extended.

The film may include a copper film and a barrier metal, and in the step (b), the copper film and the barrier metal may be polished to form a buried copper interconnect in the top of the substrate region. Therefore, dishing of the copper interconnect can be reduced as compared with the known method, thereby providing reduced interconnect resistance, dropped rate of incidence of interconnection failure and the like.

The step (a) and the step (b) may be carried out simultaneously. Therefore, when the polishing time becomes rate-determining, the time required for the process can be shortened. Furthermore, the surface roughness of the polishing pad can be kept adequate through a period of the step (b).

A second chemical mechanical polishing method of the present invention using a chemical mechanical polishing apparatus comprising a polishing table including a rotation mechanism, a polishing pad attached on the polishing table, a substrate carrier for holding a member to be polished, said substrate carrier including a rotation mechanism and a pressurization mechanism, and a dresser including a rotation mechanism and a pressurization mechanism, comprises the steps of: (a) bringing the dresser into contact with the polishing pad by applying a dressing pressure of 18 g/cm² to 40 g/cm² inclusive to the dresser to dress the polishing pad; and (b) polishing a film using the polishing pad in a pattern formation substrate including a substrate region in the top of which a trench is formed and the film with which the trench is filled in.

According to this method, the step (a) enables the surface roughness of the polishing pad to be within an adequate range. Therefore, in the step (b), dishing produced in the film can be reduced as compared with the known method. Furthermore, the removal rate of the film and the transfer reliability of the substrate hardly change as compared with the known method.

In the step (a), a dressing pressure of 24 g/cm² to 34 g/cm² inclusive is more preferably applied to the dresser.

A first chemical mechanical polishing apparatus of the present invention comprises: a polishing table including a rotation mechanism; a polishing pad for polishing a member to be polished, said polishing pad being attached on the polishing table; a substrate carrier for holding the member to be polished, said substrate carrier including a rotation mechanism and a pressurization mechanism; a dresser to make the surface of the polishing pad rough, said dresser including a rotation mechanism and a pressurization mechanism; torque measuring means for measuring a rotational torque produced between the dresser and the polishing pad, said torque measuring means being attached to the dresser; and a torque monitor for monitoring the rotational torque measured by the torque measuring means.

According to this structure, the rotational torque at dressing can be monitored. Thus, if the adequate range of the rotational torque has already been known, it is possible to sound an alarm or stop dressing at the time that the observed rotational torque deviates from the adequate range. Therefore, according to the first chemical mechanical polishing apparatus of the present invention, an adequate dressing can be performed with stability, and non-uniformity in polishing can be suppressed.

A second chemical mechanical polishing apparatus of the present invention comprises: a polishing table including a rotation mechanism; a polishing pad for polishing a member to be polished, said polishing pad being attached on the polishing table; a substrate carrier for holding the member to be polished, said substrate carrier including a rotation mechanism and a pressurization mechanism; a dresser to make the surface of the polishing pad rough, said dresser including a rotation mechanism and a pressurization mechanism; an irradiation device for irradiating the surface of the polishing pad with a laser beam or an electromagnetic wave; a detector for detecting the laser beam or the electromagnetic wave reflected by the surface of the polishing pad; and a controller for controlling the pressure to be applied to the dresser in accordance with the intensity of the laser beam or the electromagnetic wave detected by the detector.

According to this structure, the intensity of the laser beam or electromagnetic wave reflected by the polishing pad can indicate whether or not the roughness of the surface of the polishing pad is adequate, and in accordance with the result, the controller can control the dressing pressure to an adequate value. Therefore, according to the second chemical mechanical polishing apparatus of the present invention, the polishing pad can always be kept in an adequate dressing condition, thereby stably reducing dishing of the copper interconnect at formation of a buried copper interconnect or in like cases.

A third chemical mechanical polishing apparatus of the present invention comprises: a polishing table including a rotation mechanism; a polishing pad for polishing a member to be polished, said polishing pad being attached on the polishing table; a substrate carrier for holding the member to be polished, said substrate carrier including a rotation mechanism and a pressurization mechanism; a dresser to make the surface of the polishing pad rough, said dresser including a rotation mechanism and a pressurization mechanism; a transmitter for irradiating the polishing pad with an electromagnetic wave, said transmitter being attached to the dresser; a receiver for receiving the electromagnetic wave reflected by the polishing pad; and a time measuring device for measuring the time required from when the electromagnetic wave is transmitted from the transmitter to when the electromagnetic wave is received by the receiver, said time measuring device being connected to the receiver.

According to this structure, the apparatus can be controlled at suspension of dressing so that the space between the dresser and the polishing pad is kept constant. Therefore, the dressing pressure as set can certainly be applied to the dresser. Consequently, an adequate dressing can be performed with stability, thereby stably forming a buried copper interconnect and a device isolation dielectric in which dishing is reduced.

### BRIEF DESCRIPTION OF THE DRAWINGS

FIG. 1 is a schematic view showing the structure of a chemical mechanical polishing apparatus used for a chemical mechanical polishing method according to a first embodiment of the present invention.

FIG. 2 is a graph showing the relationship between the dressing pressure and the removal rate of copper on a substrate with no pattern and results obtained by measuring non-uniformity in the removal rate within the surface.

FIG. 3 is a graph showing the relationship between the dressing pressure and the removal rate of a barrier metal on a substrate with no pattern and results obtained by measuring non-uniformity in the removal rate within the surface.

FIG. 4 is a graph showing measurement results of the relationship between the dressing pressure and dishing with respect to a substrate including a buried copper interconnect.

FIG. 5 is a schematic view showing the structure of a chemical mechanical polishing apparatus according to a second embodiment of the present invention.

FIG. 6 is a schematic view showing the structure of a variant of the chemical mechanical polishing apparatus according to the second embodiment.

FIG. 7 is a schematic view showing the structure of a chemical mechanical polishing apparatus according to a third embodiment of the present invention.

FIGS. 8A through 8D are cross sectional views showing a typical method for forming a buried copper interconnect using CMP up to a process step of depositing a barrier metal.

FIGS. 9A through 9C are cross sectional views showing the typical method for forming a buried copper interconnect using CMP.

FIG. 10 is a view schematically showing the structure of a known chemical mechanical polishing apparatus.

FIGS. 11A through 11C are cross sectional views schematically showing a polishing pad when dressing is excessive, adequate and insufficient, respectively; and FIG. 11D is a cross sectional view schematically showing a polishing pad whose surface includes wave components.

### DETAILED DESCRIPTION OF THE INVENTION

—Search for Cause of Dishing—

The present inventors carried out various experiments under different conditions to find the conditions under which dishing caused by CMP can be reduced. In the course of these experiments, they found the fact that the surface roughness of a polishing pad significantly affects the occurrence of dishing. Their studies of the surface roughness of the polishing pad will be described hereinafter step by step.

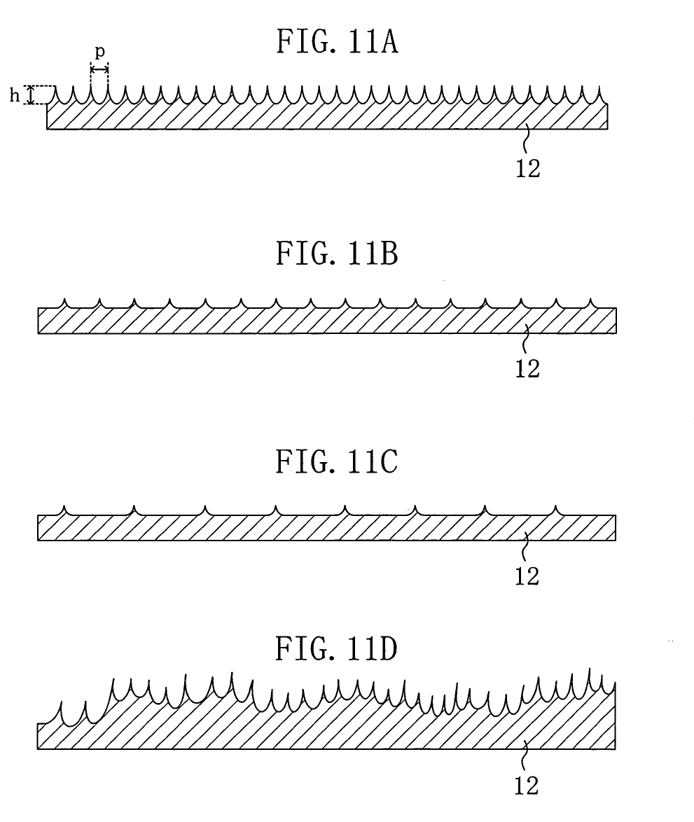

FIGS. 11A through 11C are cross sectional views schematically showing a polishing pad 12 when dressing is excessive, adequate and insufficient, respectively; and FIG. 11D is a cross sectional view schematically showing the polishing pad 12 whose surface includes wave components.

As shown in FIG. 11D, the surface of an actual polishing pad 12 has different heights at the roots of raised fibers in nap texture, depending on parts of the cloth. Such surface asperities of the polishing pad 12 are referred to as a “wave”. More specifically, the surface of the polishing pad 12 shown in FIG. 11A is obtained by removing “wave” components from the surface of the polishing pad 12 shown in FIG. 11D. The “surface roughness (top surface roughness)” used herein later means a peak-to-valley distance of a roughness curve (h shown in FIG. 11A, for example), wherein the roughness curve is obtained by removing wave components from the profile curve of the surface.

The surface roughness of the polishing pad 12 is determined by dressing. After the present inventors' studies, they found that problems are caused when dressing is excessive and insufficient, respectively.

When dressing is excessively carried out, as shown in FIG. 11A, the density of the “raised fibers” located on the surface of the polishing pad 12 is increased, and simultaneously the surface roughness increases. Here, the density of the raised fibers can be calculated from the pitch p of the raised fibers shown in this figure, for example.

An excessive dressing is caused by increasing the dressing load, increasing the relative velocity of the polishing pad 12 to a dresser or extending the dressing time. In this case, there are advantages such as enhanced removal rate, improved polishing non-uniformity within the surface of the polished substrate, improved polishing non-uniformity between substrates, and enhanced transfer reliability. This reason is as follows: in addition to physical effects, abrasive grains are easily held in slurry and the substrate can be prevented from being brought in close contact with the polishing pad 12. When a substrate having no pattern on the top surface thereof is polished, even the excessive dressing has no problem. On the other hand, when a substrate having a pattern such as a copper interconnect on the top surface thereof is polished, increased surface roughness of the polishing pad results in increased dishing occurring in the copper interconnect or the like. Therefore, the interconnect resistance may be increased and/or redundant substance to be polished may be partly left in an upper layer of the multi-level interconnect structure. In addition, enhanced dressing accelerates the wear of the polishing pad, the dresser and the like and increases the frequency with which these consumable members are exchanged, leading to problems such as reduced productivity and increased production cost. In this case, the dressing load is, for example, 70 g/cm³.

As shown in FIG. 11B, when an adequate dressing is carried but, the removal rate can be sufficiently accelerated, and also the advantages such as improved polishing non-uniformity within the surface, improved polishing non-uniformity between substrates, and enhanced transfer reliability can be obtained. In addition, as will be described later, the dishing of the copper interconnect is reduced.

Next, as shown in FIG. 11C, when dressing is insufficient, the density of the raised fibers becomes lower and the surface roughness becomes small. To be specific, an insufficient dressing is caused by reducing the dressing load, reducing the relative velocity of dressing or shortening the dressing time. The surface of the polishing pad 12 after polishing has its effective hardness reduced, but when this is subjected to an adequate dressing, there again appears a fresh surface thereof with a high cutting force. However, an insufficient dressing disables the surface thereof with a weak cutting force to be removed, resulting in a significantly reduced polishing force. Thus, although the dishing of the copper interconnect is initially suppressed, there occur the problems such as reduced removal rate, increased polishing non-uniformity within the surface, increased polishing non-uniformity between substrates, and reduced transfer reliability. When dressing is insufficiently carried out another few or more times, the surface of the polishing pad cannot be removed with it left as softened. Thus, the dishing contrariwise becomes large.

In consideration of the result of the studies described so far, there arises a suspicion that a conventional dressing pressure of 70 g/cm² is actually excessive.

The relationship between the intensity of dressing and the size of dishing, which was described above, is not restrictive at formation of a buried copper interconnect but can also be applied at formation of a trench isolation of a semiconductor device.

—Studies of Dressing Pressure—

As described above, in the case where a buried copper interconnect is formed or like cases, the selection of an adequate dressing condition leads to reduction in dishing. The dressing pressure among the dressing conditions exerts a significant influence on the surface shape of the polishing pad 12. In the light of this knowledge, in order to find an adequate dressing condition, the present inventors measured the removal rates of copper and a barrier metal, the size of dishing at the formation of the buried copper interconnect, and the like with the dressing pressure being changed within the range including the conventional pressure and less. The same chemical mechanical polishing apparatus as the known one was employed in the measurements.

First, the present inventors measured a substrate with no pattern formed on a surface to be polished, thereby identifying the range of dressing pressures under which an adequate polishing (removal) rate is obtained.

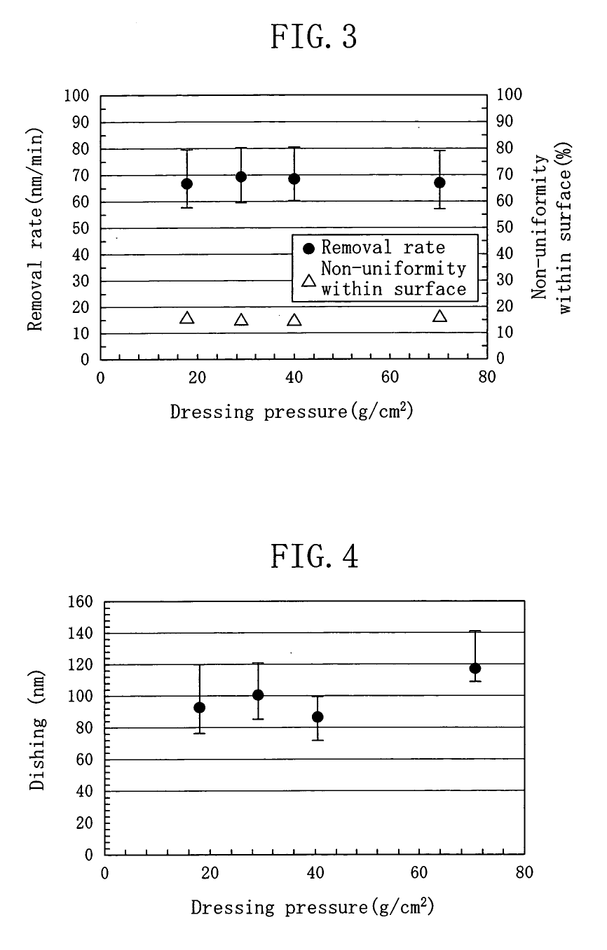

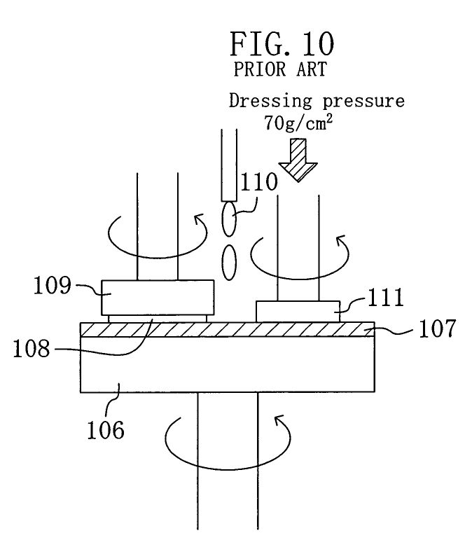

FIG. 2 is a graph showing the relationship between the dressing pressure and the removal rate of copper on a substrate with no pattern and results obtained by measuring non-uniformity in the removal rates within the surface. FIG. 3 is a graph showing the relationship between the dressing pressure and the removal rate of a barrier metal on a substrate with no pattern and results obtained by measuring non-uniformity in the removal rates within the surface. These measurements were made using the known chemical mechanical polishing apparatus shown in FIG. 10, wherein the relative velocity of dressing was approximately 1015mm/sec. FIGS. 2 and 3 each show a maximum value, a minimum value and an average value of removal rate measured under each dressing pressure, wherein these values were obtained by almost uniformly taking 27 points of measurement in a wafer and measuring the removal rate at each point of measurement. The non-uniformity in removal rate within the surface was calculated from 100×{(maximum measurement value)-(minimum measurement value)}/{2×(average measurement value)}.

The results shown in FIG. 2 indicate that the removal rate of copper did not change between the case where the dressing pressure was the conventional value, 70 g/cm², and the case where it was 18 to 40 g/cm². It is considered from the neighboring measurement values that when the dressing pressure is 40 to 70 g/cm², the removal rate does not change in the same manner. Thus, after all, in the case where the dressing pressure is 18 g/cm² or more but smaller than 70 g/cm², it is considered that the removal rate of copper is generally the same as in the known case. In addition, the non-uniformity in the removal rates in the wafer tends to become small to some extent under a dressing pressure smaller than 70 g/cm². For the dressing pressures smaller than 18 g/cm², the non-uniformity was not measured. The reason is that it is difficult to perform dressing control using a chemical mechanical polishing apparatus with a high accuracy.

The results shown in FIG. 3 indicate that the removal rate of a barrier metal also hardly changed between the case where the dressing pressure was the conventional value, 70 g/cm², and the case where it was 18 g/cm² or more but smaller than 70 g/cm². Also, it was not found that the non-uniformity in the removal rates within the surface changed in a dressing pressure range of 18 g/cm² to 70 g/cm² both inclusive.

In the above-mentioned experiments, there did not occur any transfer problem that the substrate was stuck to the polishing pad in the dressing pressure range of 18 g/cm² to 70 g/cm² both inclusive. Therefore, it can be said that the polishing characteristics and transfer reliabilities of both of copper and the barrier metal are maintained in the dressing pressure range of 18 g/cm² to 70 g/cm² both inclusive.

Next, the present inventors made measurements, on a substrate in the upper part of which a buried copper interconnect was formed, for the relationship between the dressing pressure and the size of dishing caused in the copper interconnect.

FIG. 4 is a graph showing results obtained by measuring the relationship between the dressing pressure and dishing with respect to the substrate including the buried copper interconnect. The relative velocity of dressing in this case was the same as in the measurements shown in FIGS. 2 and 3, and the trace width of the copper interconnect was approximately 80 μm. The results shown in the figure indicate, under each dressing pressure condition, the average of measurement values at plural points on the wafer, and each of error bars shows a maximum measurement value and a minimum measurement value. The dishing was detected using an atomic force microscope.

The results shown in FIG. 4 indicate that when the dressing pressure was at least 18 g/cm² and at most 40 g/cm², dishing became smaller with a statistical significance as compared with when it was 70 g/cm². When the dressing pressure was 70 g/cm², the surface roughness was larger than 10 μm but not more than 12 μm.

From the results described so far, it has been found that the dressing pressure based on the conventional conditions is excessive and a dressing pressure of 18 g/cm² or more but smaller than 70 g/cm² enables dishing to become smaller with the polishing characteristics being kept. More particularly, a dressing pressure of at least 18 g/cm² and at most 40 g/cm² enables dishing to become significantly small. In view of the extension of a dresser's life, the stability of a chemical mechanical polishing apparatus and the like, the dressing pressure is most preferably at least 24 g/cm² and at most 34 g/cm².

In this way, the dressing pressure is set to an adequate value, thereby reducing dishing. Furthermore, the dressing pressure is reduced to be smaller than the conventional value, thereby extending the dresser's life and reducing the production cost of a semiconductor device.

(Embodiment 1)

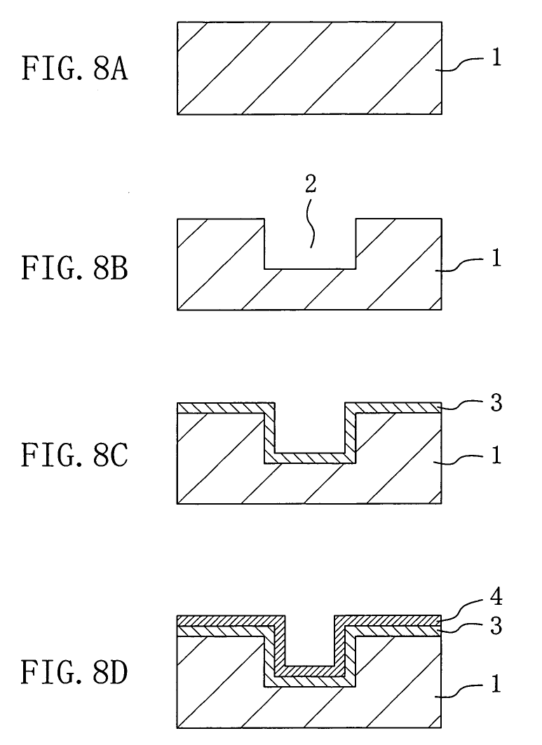

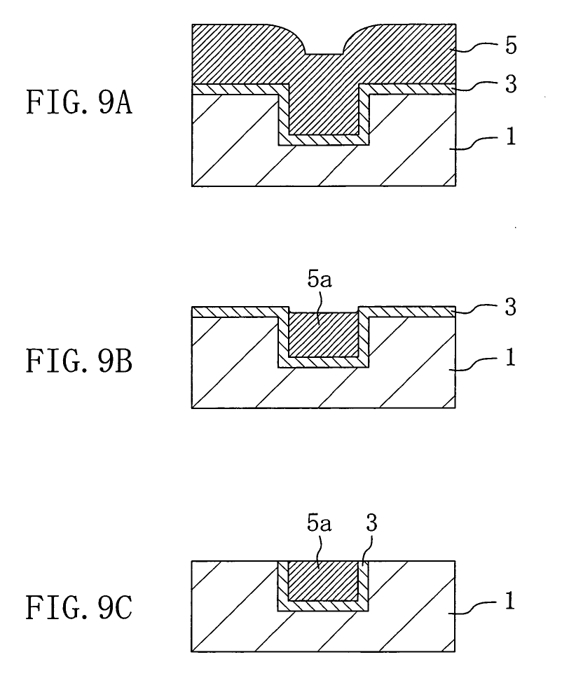

A description will be given of an embodiment of a CMP method to which optimum dressing conditions derived from the above-mentioned experiment results are applied. A whole process for forming a buried copper interconnect including a CMP process is the same as the method described with reference to FIGS. 8A through 8D and 9A through 9C. Thus, the contents of the CMP process will be described hereinafter.

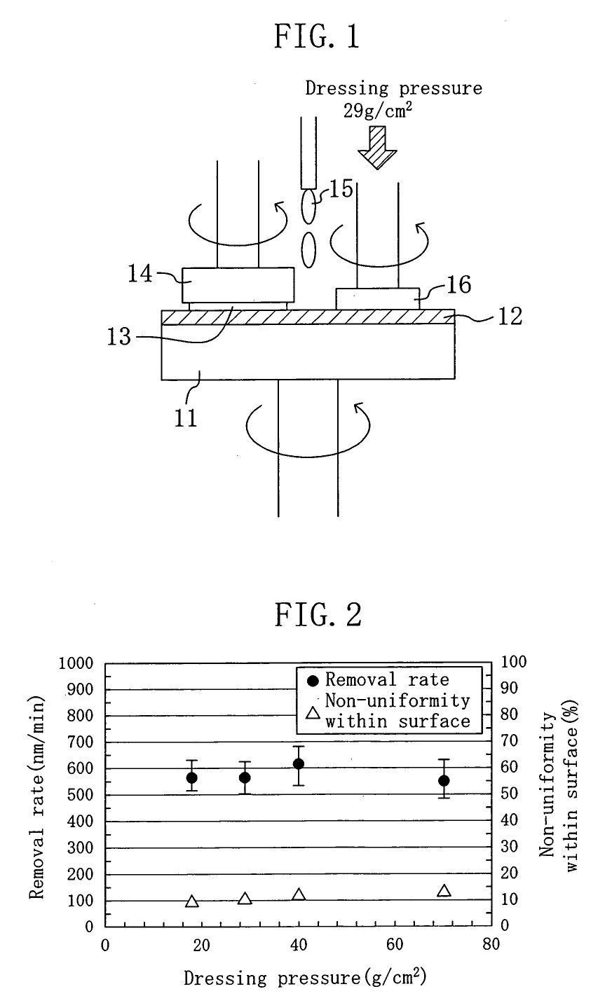

FIG. 1 is a schematic view showing the structure of a chemical mechanical polishing apparatus used for a chemical mechanical polishing method according to a first embodiment of the present invention. As shown in this figure, the chemical mechanical polishing apparatus used for the chemical mechanical polishing method of this embodiment is the same as the known one.

More specifically, the chemical mechanical polishing apparatus used in this embodiment comprises a polishing table 11 to the top surface of which a polishing pad 12 is attached, a substrate carrier 14, including a rotation mechanism and a pressurization mechanism, for holding a substrate 13 to be polished, and a dresser 16, including a rotation mechanism and a pressurization mechanism, to make the surface of the polishing pad 12 rough. According to the chemical mechanical polishing method of this embodiment, when a copper film is polished, dressing is carried out under a dressing pressure of 29 g/cm² simultaneously with or before the polishing of the substrate. When dressing is carried out separately from the polishing, the dressing time is approximately 15 sec. When dressing is carried out simultaneously with the polishing, the dressing time is the same (approximately 45 sec) as the polishing time. Thereby, the surface roughness of the polishing pad 12 becomes at least 6 μm and at most 8 μm. This surface roughness is a value obtained by being measured using a stylus surface roughness gauge, for example. FIG. 1 shows an example in which dressing and polishing are carried out at the same time, and the relative velocity of dressing is, for example, 1015 mm/sec. As shown in FIG. 9, the substrate 13 has a trench having, for example, a width of 10 μm provided at the surface-to-be-polished side and is in the state where a barrier metal and copper are successively deposited on the top surface of the substrate including this trench.

In the step of polishing a copper film in the chemical mechanical polishing method of this embodiment, the substrate 13 is put down onto the polishing pad 12 by imposing a load on the substrate carrier 14 that holds the substrate 13 with the surface of the substrate 13 to be polished being directed to the polishing pad 12. While slurry 15 is supplied on the polishing pad 12, both of the polishing table 11 and the substrate carrier 14 are rotated. Here, the slurry 15 contains a component oxidizing and dissolving copper, thereby polishing the copper film on the substrate 13 until the barrier metal is exposed.

In the subsequent step of polishing the barrier metal, the substrate 13 is taken out of this chemical mechanical polishing apparatus, and the substrate 13 is placed in a chemical mechanical polishing apparatus for polishing a barrier metal. This chemical mechanical polishing apparatus also has the same structure as the chemical mechanical polishing apparatus shown in FIG. 1. This apparatus also performs dressing under a dressing pressure of 29 g/cm² for approximately 15 or 45 seconds, resulting in the surface roughness of the polishing pad 12 becoming at least 6 μm and at most 8 μm. The relative velocity of the dressing is the same as when copper is polished. The slurry 15 used in this step contains a component for oxidizing and dissolving the barrier metal, and is prepared so that the removal rate of the barrier metal will be equivalent to or faster than that of copper.

The copper film and the barrier metal may be polished using the same chemical mechanical polishing apparatus. However, when the copper film and the barrier metal are polished using different chemical mechanical polishing apparatuses, there is the advantage that contamination with the remaining slurry or the like hardly occurs.

According to the chemical mechanical polishing method of this embodiment, a semiconductor device having dishing reduced substantially in the same polishing time as in the known method can be fabricated. Thereby, the possibilities of a short circuit between interconnect traces and an interconnection failure can be reduced.

The size of the dishing can similarly be reduced by reducing the relative velocity of dressing, shortening the dressing time, for example, from 45 seconds to 30 seconds, or the like.

According to the chemical mechanical polishing method of this embodiment, as described above, the dressing step may be performed before or simultaneously with the step of polishing the copper film or the barrier metal. However, when dressing and polishing are performed simultaneously, the time required for the whole process can be shortened, and also the surface roughness of the polishing pad can properly be held with ease through the polishing step.

When the chemical mechanical polishing apparatus shown in FIG. 1 is employed, 18 through 40 g/cm² is the adequate dressing pressure. However, when a chemical mechanical polishing apparatus of different specification is employed, the range of the adequate dressing pressure may change. Also in this case, the surface roughness of the polishing pad is set to at least 6 μm and at most 8 μm so that an adequate dressing is carried out.

The chemical mechanical polishing method of this embodiment can be applied at formation of an STI. In this case, a SiO₂ film is formed on the surface in which a trench is formed, and thereafter this SiO₂ film is polished. Thereby, dishing produced in a dielectric for device isolation can become smaller than produced in the known method. Furthermore, the polishing non-uniformity within the substrate surface can be reduced to a smaller extent than that in the known method. In addition, since the dresser's life can become longer, the cost required for CMP can be reduced. Furthermore, transfer reliability can be made equivalent to the known method.

(Embodiment 2)

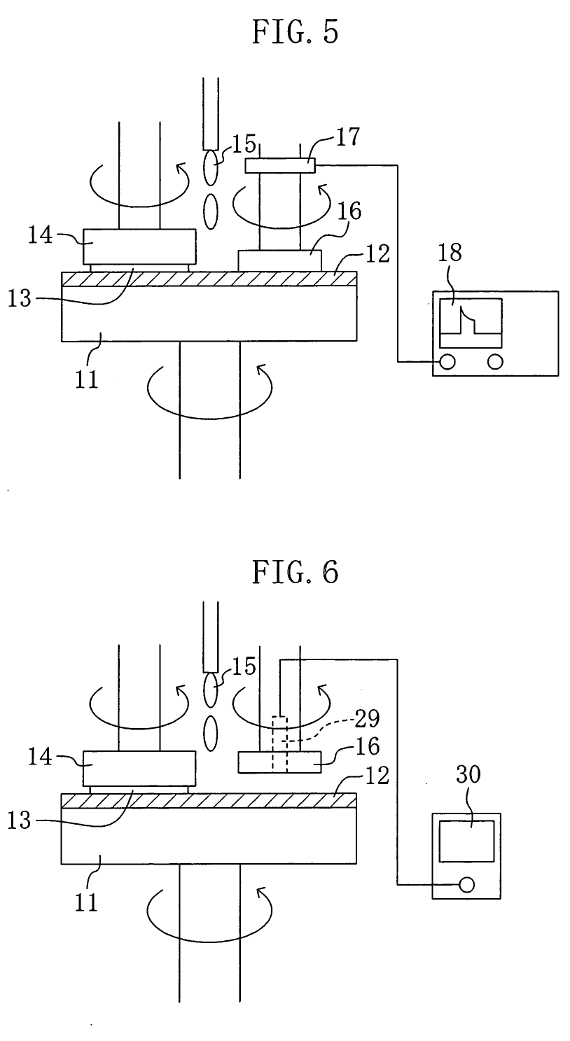

FIG. 5 is a schematic view showing the structure of a chemical mechanical polishing apparatus according to a second embodiment of the present invention. The characteristic of the chemical mechanical polishing apparatus of this embodiment is that the surface roughness of a polishing pad is monitored in carrying out dressing before or simultaneously with polishing. Its details will be described hereinafter.

The chemical mechanical polishing apparatus used in this embodiment comprises a polishing table 11 to the top surface of which a polishing pad 12 is attached, a substrate carrier 14 for holding a substrate 13 to be polished, and a dresser 16 to make the surface of the polishing pad 12 rough, like the apparatus used in the first embodiment. In addition, a torque measuring device 17 is attached to the dresser 16 of the chemical mechanical polishing apparatus of the present invention and connected to a torque monitor 18.

When the substrate 13 is polished, the substrate 13 is put down onto the polishing pad 12 by imposing a load on the substrate carrier 14 that holds the substrate 13 with the surface of the substrate 13 to be polished being directed to the polishing pad 12. While slurry 15 is supplied on the polishing pad 12, both of the polishing table 11 and the substrate carrier 14 are rotated. Dressing of the polishing pad 12 is performed before polishing or during polishing.

Since the chemical mechanical polishing apparatus of this embodiment comprises the torque measuring device 17, whether the surface of the polishing pad 12 has an adequate roughness at dressing can indirectly be monitored. A torque means a vector indicating a moment, and its magnitude is represented by (gyration radius)×(turning force).

The top surface roughness (surface roughness) of the polishing pad 12 can be monitored as follows.

First, when dressing is adequately performed, the amplitude of a torque waveform is stable at a fixed value.

On the other hand, it is assumed that, for example, the dressing pressure increases due to any cause. At this time, in order to maintain the rotation of the dresser 16 as set, the turning force of the dresser must be increased. The increased dressing pressure results in an excessive dressing. Therefore, the excessive dressing also leads to an increase in the rotational torque of the dresser 16, whereby the amplitude of the monitored rotational torque waveform becomes larger.

Conversely, for example, it is assumed that the dressing pressure decreases due to any cause. At this time, a smaller torque than so far is only required to maintain the rotation of the dresser 16 as set. When the dressing pressure becomes small, dressing becomes insufficient. Therefore, when dressing is insufficient, i.e., dressing is not performed enough, the rotational torque of the dresser 16 decreases and the amplitude of the monitored rotational torque waveform also decreases.

In this way, the measurement of a rotation torque waveform reveals whether dressing is adequately performed. According to this embodiment, the rotational torque waveform is monitored by the torque monitor 18. The torque monitor is additionally provided with a torque controller that can give an alarm and make the polishing apparatus side suspend the process when the waveform amplitude exceeds the upper and lower limits of a standard width. That is, when the rotational torque waveform is stable, the surface roughness of the polishing pad becomes constant. This provides a stable chemical mechanical polishing of the copper interconnect. Here, the torque range is set such that the dressing pressure is, for example, 18 through 40 g/cm².

As described above, according to the chemical mechanical polishing apparatus of this embodiment, the surface roughness of the polishing pad subjected to dressing is indirectly monitored at least during polishing, and the rotational torque of dressing is kept constant, thereby accurately controlling the dressing pressure. Since the dishing of the copper interconnect can consequently become small with stability, a semiconductor integrated circuit with high reliability can be provided with stability.

—Variant of Second Embodiment—

FIG. 6 is a schematic view showing the structure of a variant of the chemical mechanical polishing apparatus according to the second embodiment of the present invention.

The chemical mechanical polishing apparatus according to the second embodiment of the present invention is controlled by the torque measuring device and the torque monitor so as to perform an adequate dressing. However, the other means can also properly control the dressing of the polishing pad.

For example, even when the chemical mechanical polishing apparatus is additionally provided with a laser irradiation device, a laser power detector for detecting laser light reflected by the polishing pad 12, an amplifier for amplifying a detection signal, and a controller for controlling the dressing pressure, it can be controlled so as to perform an adequate dressing.

The polishing pad 12 is irradiated with laser light having, for example, a wavelength of 633 nm from the laser irradiation device during dressing or after dressing, and the laser power detector detects the laser light reflected by the polishing pad 12.

In an example shown in FIG. 6, a laser transmitter/receiver 29 obtained by integrating the laser irradiation device and the laser power detector is provided at the center of the dresser 16. An amplifier 30 connected to the laser transmitter/receiver 29 can amplify a detection signal from the laser transmitter/receiver 29.

The larger the surface roughness of the polishing pad 12 becomes, the larger the scattering of laser light becomes. Therefore, the intensity of laser light detected by the laser power detector accordingly becomes weaker. In view of this, the adequate intensity range of laser light is previously set. Thus, when the intensity of the laser light detected by the laser power detector (the laser transmitter/receiver 29) deviates from the adequate range, an adequate dressing can be performed by the controller giving an alarm and changing the dressing pressure.

Although an example in which the laser irradiation device and the laser power detector are integrated is taken here, both of them may be provided separately.

(Embodiment 3)

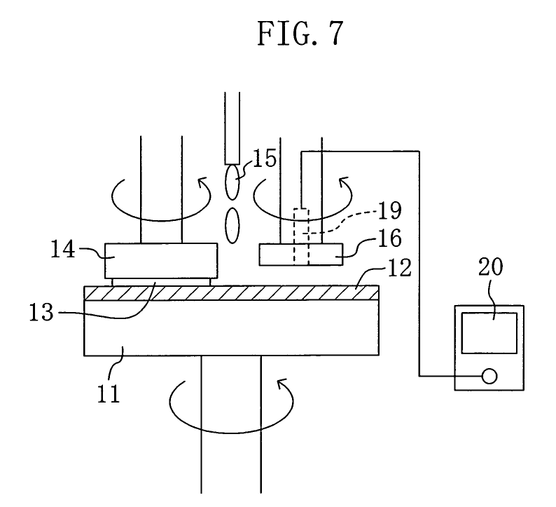

FIG. 7 is a schematic view showing the structure of a chemical mechanical polishing apparatus according to a third embodiment of the present invention. The chemical mechanical polishing apparatus of this embodiment is characterized in that the distance between a dresser and a polishing pad is always kept constant in a quiescent state. Its details will be described hereinafter.

As shown in FIG. 7, the chemical mechanical polishing apparatus of this embodiment comprises a polishing table 11 to the top surface of which a polishing pad 12 is attached, a substrate carrier 14 for holding a substrate 13 to be polished, and a dresser 16 to make the surface of the polishing pad 12 rough, like the apparatus used in the first embodiment. In addition, an electromagnetic wave transmitter/receiver 19 is attached to the dresser 16 and connected to a time-measuring device 20.

When the substrate 13 is polished, the substrate 13 is put down onto the polishing pad 12 by imposing a load on the substrate carrier 14 that holds the substrate 13 with the surface of the substrate 13 to be polished being directed to the polishing pad 12. While slurry 15 is supplied on the polishing pad 12, both of the polishing table 11 and the substrate carrier 14 are rotated. Dressing of the polishing pad 12 is performed before polishing or during polishing.

According to the chemical mechanical polishing apparatus of the present invention, in order to measure the distance between the dresser 16 and the polishing pad 12 in a quiescent state, the electromagnetic wave transmitter/receiver 19 is attached to the center of the circular dresser 16 to transmit and receive an electromagnetic wave such as a microwave, and this electromagnetic wave transmitter/receiver 19 is connected to the time-measuring device 20 for measuring the traveling time of the electromagnetic wave.

When a dressing operation is suspended, the surface of the dresser 16 to which diamond grains are adhered remains stationary while keeping a fixed distance from the polishing pad 12. It is not until the dressing operation is started that the air is fed to the dresser 16, which then reaches the surface of the polishing pad 12. At this time, the relationship between the air pressure and the output of a dressing load is calibrated on the premise that the traveling distance of the dresser 16 is constant. Therefore, the traveling distance, i.e., the distance between the dressing surface of the dresser 16 and the polishing pad 12 need always be kept constant so as to perform an adequate dressing. For example, when the distance between the dresser 16 and the polishing pad 12 is larger than a set value, the dressing pressure becomes smaller than the set one, resulting in an insufficient dressing. When the distance between the dresser 16 and the polishing pad 12 is larger than the set value, the dressing pressure becomes larger than the set one, resulting in an excessive dressing.

Since in the known chemical mechanical polishing apparatus the dresser 16 is manually aligned in a quiescent state, there may be a case where dressing is not performed as set. On the other hand, according to the chemical mechanical polishing apparatus of this embodiment, the functions of the electromagnetic wave transmitter/receiver 19 and the time-measuring device 20 enable the dresser 16 in a quiescent state to remain stationary at a predetermined position. Thus, the error of dressing can be reduced.

Here, the functions of the electromagnetic wave transmitter/receiver 19 and the time-measuring device 20 will be described more specifically. As described above, the electromagnetic wave transmitter/receiver 19 of this embodiment combines the function of transmitting an electromagnetic wave such as a microwave and the function of receiving the electromagnetic wave.

First, when polishing is completed so that the dresser 16 is raised or comes into a quiescent state, the electromagnetic wave transmitter/receiver 19 irradiates the polishing pad 12 with a microwave. This microwave is reflected on the surface of the polishing pad 12 getting wet with moisture and again received by the electromagnetic wave transmitter/receiver 19. The reason why an electromagnetic wave including a microwave is employed is that such an electromagnetic wave causes a reflection phenomenon on the interface between substances having different conductivities. In an example of this embodiment, since the surface of the polishing pad 12 with moisture has a higher conductivity than the air, a reflection phenomenon occurs.

Subsequently, when the microwave is received by the electromagnetic wave transmitter/receiver 19, the time required from when the microwave is transmitted to when it is received is measured by the electromagnetic wave transmitter/receiver 19. The time measured here is referred to as the propagation time of the microwave. The transfer rate of the microwave depends on the temperature and humidity of the air through which the microwave propagates. Therefore, the propagation rate of the microwave can be calculated by measuring the temperature and humidity of the air at the time measurement. The traveling distance of the dresser 16 can be calculated from the propagation time and propagation rate of the microwave thus obtained. To be specific, this is determined as follows.

(traveling distance of dresser)=(propagation rate)×(propagation time)/2 (1)

This calculation is carried out by the time measuring device 20. The dresser is controlled by a controller (not shown) or the like to always keep the distance thus obtained constant, thereby always maintaining adequate dressing.

As described above, according to the chemical mechanical polishing apparatus of this embodiment, the space between the dresser and the polishing pad is always kept constant during suspension of dressing, thereby always maintaining adequate dressing conditions. For example, the chemical mechanical polishing apparatus of this embodiment is employed under the condition that the dressing pressure is 18 through 40 g/cm², thereby stably producing a semiconductor device in which dishing of the copper interconnect is reduced.

Furthermore, according to the chemical mechanical polishing apparatus of this embodiment, the dressing pressure can be kept in an optimum condition by not only the polishing step for forming a buried copper interconnect but also various polishing steps such as a polishing step for forming a trench isolation and the step of polishing the inter-level dielectric. In addition, non-uniformity in polishing can be suppressed.

The electromagnetic wave transmitter/receiver and the time measuring device that are described in this embodiment are effective especially for a chemical mechanical polishing apparatus of the type having a load cell for measuring a load. The structure of the chemical mechanical polishing apparatus of this embodiment can preferably be applied to, for example, an apparatus to which a load cell is not attached due to a small area of the apparatus.

In the chemical mechanical polishing apparatus of this embodiment, an electromagnetic wave transmitter and receiver may be provided separately. In this case, the receiver may be placed at a position where an electromagnetic wave reflected on the substrate can effectively be received.

Furthermore, although in this embodiment, an example in which the electromagnetic wave transmitter/receiver 19 is provided at the center of the dresser 16 is taken, the transmitter/receiver may be provided, for example, on the periphery of the disk-like dresser 16.

What is claimed is:

1. A chemical mechanical polishing method using a chemical mechanical polishing apparatus comprising a polishing table including a rotation mechanism, a polishing pad attached on the polishing table, a substrate carrier for holding a member to be polished, said substrate carrier including a rotation mechanism and a pressurization mechanism, and a dresser including a rotation mechanism and a pressurization mechanism, said method comprising the steps of:
(a) dressing the polishing pad with the dresser coming in contact with the polishing pad; and
(b) polishing a film using the polishing pad having a surface roughness of 6 μm to 8 μm inclusive in a pattern formation substrate including a substrate region in the top of which a trench is formed and the film with which the trench is filled in.

2. The chemical mechanical polishing method of claim 1, wherein
in the step (a), a dressing pressure of 18 g/cm² to 40 g/cm² inclusive is applied to the dresser.

3. The chemical mechanical polishing method of claim 2, wherein
in the step (a), a dressing pressure of 24 g/cm² to 34 g/cm² inclusive is applied to the dresser.

4. The chemical mechanical polishing method of claim 1, wherein
the film includes a copper film and a barrier metal, and
in the step (b), the copper film and the barrier metal are polished to form a buried copper interconnect in the top of the substrate region.

5. The chemical mechanical polishing method of claim 1, wherein
the step (a) and the step (b) are carried out simultaneously.

6. A chemical mechanical polishing method using a chemical mechanical polishing apparatus comprising a polishing table including a rotation mechanism, a polishing pad attached on the polishing table, a substrate carrier for holding a member to be polished, said substrate carrier including a rotation mechanism and a pressurization mechanism, and a dresser including a rotation mechanism and a pressurization mechanism, said method comprising the steps of:
(a) bringing the dresser into contact with the polishing pad by applying a dressing pressure of 18 g/cm² to 40 g/cm² inclusive to the dresser to dress the polishing pad; and
(b) polishing a film using the polishing pad in a pattern formation substrate including a substrate region in the top of which a trench is formed and the film with which the trench is filled in.

7. The chemical mechanical polishing method of claim 6, wherein
in the step (a), a dressing pressure of 24 g/cm² to 34 g/cm² inclusive is applied to the dresser.

8. A chemical mechanical polishing apparatus comprising:
a polishing table including a rotation mechanism;
a polishing pad for polishing a member to be polished, said polishing pad being attached on the polishing table;
a substrate carrier for holding the member to be polished, said substrate carrier including a rotation mechanism and a pressurization mechanism;
a dresser to make the surface of the polishing pad rough, said dresser including a rotation mechanism and a pressurization mechanism;
torque measuring means for measuring a rotational torque produced between the dresser and the polishing pad, said torque measuring means being attached to the dresser; and
a torque monitor for monitoring the rotational torque measured by the torque measuring means.

9. A chemical mechanical polishing apparatus comprising:
a polishing table including a rotation mechanism;
a polishing pad for polishing a member to be polished, said polishing pad being attached on the polishing table;
a substrate carrier for holding the member to be polished, said substrate carrier including a rotation mechanism and a pressurization mechanism;
a dresser to make the surface of the polishing pad rough, said dresser including a rotation mechanism and a pressurization mechanism;
an irradiation device for irradiating the surface of the polishing pad with a laser beam or an electromagnetic wave;
a detector for detecting the laser beam or the electromagnetic wave reflected by the surface of the polishing pad; and
a controller for controlling the pressure to be applied to the dresser in accordance with the intensity of the laser beam or the electromagnetic wave detected by the detector.

10. A chemical mechanical polishing apparatus comprising:
a polishing table including a rotation mechanism;
a polishing pad for polishing a member to be polished, said polishing pad being attached on the polishing table;
a substrate carrier for holding the member to be polished, said substrate carrier including a rotation mechanism and a pressurization mechanism;
a dresser to make the surface of the polishing pad rough, said dresser including a rotation mechanism and a pressurization mechanism;
a transmitter for irradiating the polishing pad with an electromagnetic wave, said transmitter being attached to the dresser;
a receiver for receiving the electromagnetic wave reflected by the polishing pad; and
a time measuring device for measuring the time required from when the electromagnetic wave is transmitted from the transmitter to when the electromagnetic wave is received by the receiver, said time measuring device being connected to the receiver.
